(19) United States
(12) Patent Application Publication
(10) Pub. No.: US 2025/0343098 A1
(43) Pub. Date: Nov. 6, 2025

(54) SEMICONDUCTOR PACKAGE

(71) Applicant: SAMSUNG ELECTRONICS CO., LTD., SUWON-SI (KR)

(72) Inventors: Hyeonjeong HWANG, Suwon-si (KR); Kyung Don MUN, Suwon-si (KR)

(21) Appl. No.: 18/926,436

(22) Filed: Oct. 25, 2024

(30) Foreign Application Priority Data
May 3, 2024 (KR) 10-2024-0059190

(51) Int. Cl. H01L 23/367; H01L 23/00; H01L 23/498; H01L 23/538; H01L 25/10

(52) U.S. Cl. CPC H01L 23/3675; H01L 23/49816; H01L 23/5383; H01L 24/20; H01L 24/24; H01L 25/105; H01L 24/16; H01L 24/73; H01L 2224/16227; H01L 2224/215; H01L 2224/24146; H01L 2224/73259; H01L 2225/1041

(57) ABSTRACT

A semiconductor package includes a first semiconductor chip and a second semiconductor chip spaced apart from each other in a first direction. Heat transfer parts are disposed on each of the first semiconductor chip and the second semiconductor chip in a second direction intersecting the first direction. An upper wiring structure is disposed between the heat transfer parts in the first direction. A third semiconductor chip is disposed on the upper wiring structure in the second direction. The third semiconductor chip is electrically connected to the upper wiring structure. A thickness of the upper wiring structure in the second direction and a thickness of the heat transfer parts in the second direction are identical to each other.

### CROSS-REFERENCE TO RELATED APPLICATION(S)

This application claims priority under 35 U.S.C. § 119 to Korean Patent Application No. 10-2024-0059190, filed on May 3, 2024 in the Korean Intellectual Property Office, the disclosure of which is incorporated by reference in its entirety herein.

### 1. Technical Field

Example embodiments relate to a semiconductor package.

### 2. Discussion of Related Art

As the electronic industry has developed, the consumer demand for high-functioning, high-speed, and miniaturized electronic components has increased. In response to this consumer demand, a manner of stacking and mounting several semiconductor chips in one package wiring structure or of stacking a package on another package may be used. For example, a package-in-package (PIP) type semiconductor package or a package-on-package (POP) type semiconductor package may be used. However, it may be difficult for highly integrated semiconductor packages to dissipate heat. Accordingly, a heat spreader may be used for dissipating heat inside a semiconductor package.

### SUMMARY

An aspect provides a semiconductor package in which heat dissipation performance is increased.

Another aspect also provides a semiconductor package in which a risk due to asymmetrical heat generation is reduced or prevented.

Embodiments of the present disclosure are not limited to the technical features described above, and other unstated technical features may be clearly understood by those skilled in the art from the following description.

According to an embodiment of the present disclosure, a semiconductor package includes a first semiconductor chip and a second semiconductor chip spaced apart from each other in a first direction. Heat transfer parts are disposed on each of the first semiconductor chip and the second semiconductor chip in a second direction intersecting the first direction. An upper wiring structure is disposed between the heat transfer parts in the first direction. A third semiconductor chip is disposed on the upper wiring structure in the second direction. The third semiconductor chip is electrically connected to the upper wiring structure. A thickness of the upper wiring structure in the second direction and a thickness of the heat transfer parts in the second direction are identical to each other.

According to embodiment of the present disclosure, a semiconductor package includes a first semiconductor chip and a second semiconductor chip spaced apart from each other in a first direction. Heat transfer parts are disposed on each of the first semiconductor chip and the second semiconductor chip in a second direction intersecting the first direction. An upper wiring structure is disposed between the heat transfer parts in the first direction. A wiring post is disposed between the first semiconductor chip and the second semiconductor chip and positioned below the upper wiring structure in a direction opposite to the second direction. The wiring post is electrically connected to the upper wiring structure. A third semiconductor chip is disposed on the upper wiring structure in the second direction. The third semiconductor chip is electrically connected to the upper wiring structure. A bottom surface of the heat transfer parts is in direct contact with an upper surface of the first semiconductor chip and an upper surface of the second semiconductor chip. In the first direction, a distance between a central axis of the third semiconductor chip and an inner side surface of the first semiconductor chip is identical to a distance between the central axis of the third semiconductor chip and an inner side surface of the second semiconductor chip.

According to an embodiment of the present disclosure, a semiconductor package includes a first semiconductor chip and a second semiconductor chip spaced apart from each other in a first direction. Heat transfer parts are disposed on each of the first semiconductor chip and the second semiconductor chip in a second direction intersecting the first direction. An upper wiring structure is disposed between the heat transfer parts in the first direction. A third semiconductor chip is disposed on the upper wiring structure in the second direction. The third semiconductor chip is electrically connected to the upper wiring structure. A lower wiring structure is disposed below the first semiconductor chip and the second semiconductor chip in a direction opposite to the second direction. A wiring post is disposed between the first semiconductor chip and the second semiconductor chip in the first direction. The wiring post electrically connects the upper wiring structure and the lower wiring structure to each other. A heat dissipation part is spaced apart from the third semiconductor chip in the first direction. The heat dissipation part is disposed on the heat transfer parts in the second direction. A bottom surface of the heat transfer parts is in direct contact with an upper surface of the first semiconductor chip and an upper surface of the second semiconductor chip. In the first direction, the first semiconductor chip and the second semiconductor chip are symmetrically positioned based on a central axis of the third semiconductor chip. Each of the first semiconductor chip and the second semiconductor chip includes a logic chip. The third semiconductor chip includes a memory chip.

Details of non-limiting embodiments are included in the detailed description and drawings.

According to embodiments of the present disclosure, it is possible to increase heat dissipation performance in a semiconductor package.

In addition, according to embodiments of the present disclosure, it is possible to alleviate a risk due to asymmetrical heat generation in a semiconductor package.

### BRIEF DESCRIPTION OF THE DRAWINGS

These and/or other aspects, features, and advantages of the present disclosure will become apparent and more readily appreciated from the following description of non-limiting embodiments, taken in conjunction with the accompanying drawings of which:

FIG. 1 is a layout diagram of a semiconductor package according to an embodiment of the present disclosure;

FIG. 2 is a cross-sectional view taken along line A-A of FIG. 1 according to an embodiment of the present disclosure;

FIG. 3 is an enlarged view showing part P of FIG. 2 according to an embodiment of the present disclosure;

FIG. 4 is a cross-sectional view for illustrating a semiconductor package according to an embodiment of the present disclosure;

FIGS. 5 to 10 are cross-sectional views for illustrating a semiconductor package according to embodiments of the present disclosure; and

FIGS. 11 to 16 are diagrams of intermediate stages for illustrating a fabrication method of a semiconductor package according to embodiments of the present disclosure.

### DETAILED DESCRIPTION OF EMBODIMENTS

Before describing example, non-limiting embodiments in detail, the words and terminologies used in the specification and claims are not to be construed as limited to common or dictionary meanings but construed as meanings and conceptions coinciding with the technical spirit of embodiments of the present disclosure under a principle that the inventor(s) may appropriately define the conception of the terminologies to explain the invention. Therefore, the example embodiments described in the specification and the configurations illustrated in the drawings may not fully cover the spirit and scope of embodiments of the present disclosure. Accordingly, it should be understood that embodiments of the present disclosure encompass various equivalents and modifications.

In the descriptions below, a singular expression includes a plural expression unless contextually apparently otherwise defined. It should be understood that terms such as “comprise or include” or “consist of” specify the presence of a characteristic, a number, a step, an operation, an element, a component, or a combination thereof which are described in the specification and do not previously exclude the possibility of the presence or addition of one or more other characteristics, numbers, steps, operations, elements, components, or combinations thereof.

Further, in the descriptions below, expressions such as upper side, upper portion, lower side, lower portion, side surface, front surface, rear surface, and the like are represented based on directions illustrated in the drawings and may be otherwise represented when the direction of the corresponding object changes. The shapes and sizes of elements in the drawings may be exaggerated for clear descriptions.

Hereinafter, example, non-limiting embodiments according to the present disclosure are explained with reference to the attached drawings.

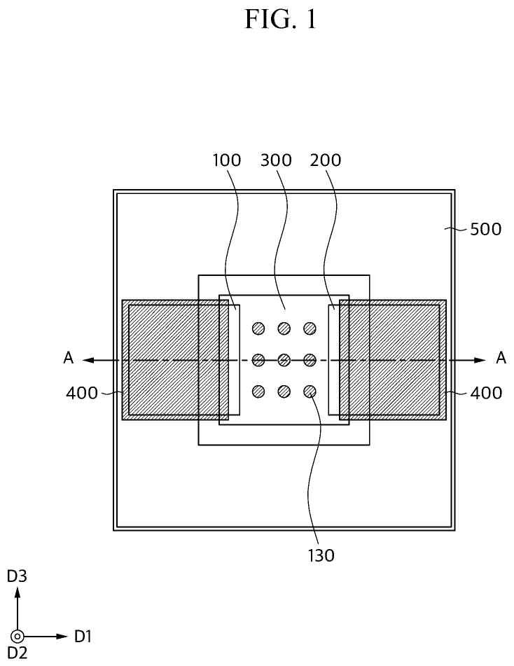

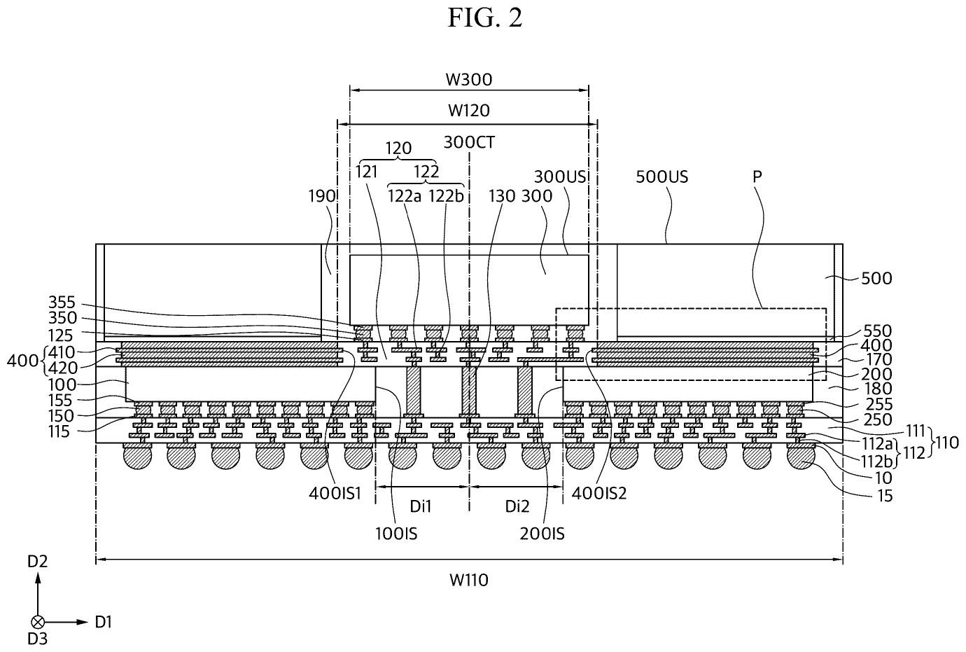

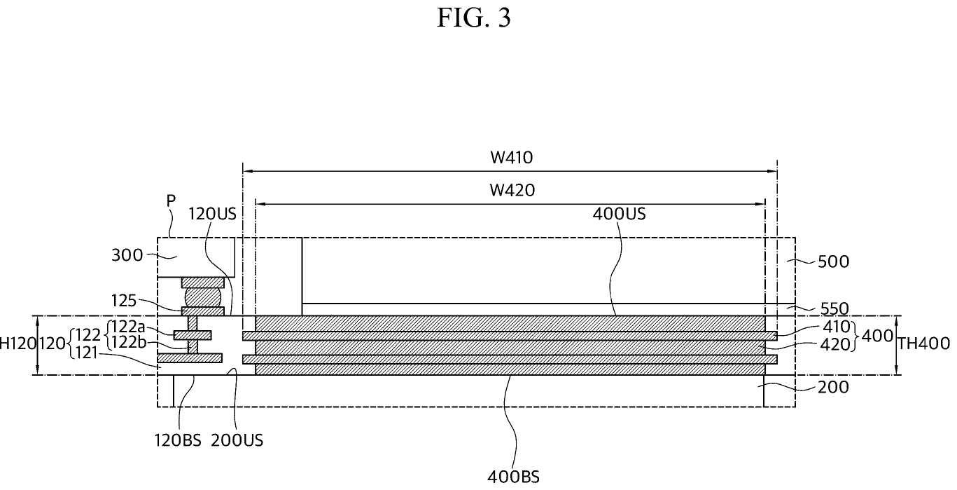

FIG. 1 is a layout diagram of a semiconductor package according to an embodiment. FIG. 2 is a cross-sectional view taken along line A-A of FIG. 1. FIG. 3 is an enlarged view showing part P of FIG. 2.

Referring to FIGS. 1 to 3, a semiconductor package according to an embodiment may include a lower wiring structure 110, a first semiconductor chip 100, a second semiconductor chip 200, an upper wiring structure 120, a wiring post 130, a third semiconductor chip 300, heat transfer parts 400, and a heat dissipation part 500.

In some embodiments, the lower wiring structure 110 may be disposed below the first semiconductor chip 100 and the second semiconductor chip 200 (e.g., in a direction opposite to the second direction D2). The lower wiring structure 110 may be electrically connected to the first semiconductor chip 100 and the second semiconductor chip 200. For example, the first semiconductor chip 100 and the second semiconductor chip 200 may exchange electrical signals with an external apparatus through the lower wiring structure 110.

In some embodiments, the lower wiring structure 110 may be a wiring board for a package. For example, in an embodiment the lower wiring structure 110 may be a printed circuit board (PCB) or a ceramic wiring board. Alternatively, the lower wiring structure 110 may also be a wiring board for a wafer-level package (WLP) fabricated at a wafer level.

In some embodiments, the lower wiring structure 110 may include a lower insulation layer 111 and a lower wiring line 112.

In some embodiments, the lower insulation layer 111 may include a photoimageable dielectric. For example, the lower insulation layer 111 may include a photosensitive polymer. In an embodiment, the photosensitive polymer may be formed with, for example, at least one of photosensitive polyimide, polybenzoxazole, phenolic polymer, and benzocyclobutene-based polymer. However, embodiments of the present disclosure are not necessarily limited thereto. For example, in an embodiment the lower insulation layer 111 may be formed with a silicon oxide layer, a silicon nitride layer, or a silicon oxynitride layer.

In some embodiments, the lower wiring structure 110 may include a substrate. For example, in an embodiment the substrate of the lower wiring structure 110 may be a PCB or a ceramic substrate. However, embodiments of the present disclosure are not necessarily limited thereto.

In some embodiments, the substrate of the lower wiring structure 110 may consist of at least one material selected among phenolic resin, epoxy resin, and polyimide. The substrate of the lower wiring structure 110 may include at least one material selected among tetrafunctional epoxy, polyphenylene ether, epoxy/polyphenylene oxide, bismaleimide triazine (BT), thermount, cyanate ester, and liquid crystal polymer.

In some embodiments, the substrate of the lower wiring structure 110 may include a resin impregnated into a core material such as glass fiber (or glass cloth or glass fabric), for example, prepreg, Ajinomoto build-up film (ABF), FR-4, or Bismaleimide Triazine (BT), along with an inorganic filler.

In an embodiment, on the lower wiring structure 110, a passivation layer may be formed to protect the lower wiring line 112 within the lower wiring structure 110 and other structures from external impacts or moisture. For example, in an embodiment a passivation film including a solder resist may be formed on a surface of the lower insulation layer 111. However, embodiments of the present disclosure are not necessarily limited thereto.

In some embodiments, the lower insulation layer 111 is a single layer. However, embodiments of the present disclosure are not necessarily limited thereto. For example, the lower insulation layer 111 may also be formed as a multilayer to surround the multilayer lower wiring line 112.

In some embodiments, the lower wiring line 112 may be disposed within the lower insulation layer 111. In an embodiment, the lower wiring line 112 may include a lower wiring pattern 112a and a lower wiring via 112b extending in a vertical direction (e.g., the second direction D2) to connect each of the lower wiring patterns 112a disposed on different vertical levels from each other. For example, the lower wiring line 112 may be a multilayer structure in which two or more lower wiring patterns 112a or two or more lower wiring vias 112b are alternately stacked (e.g., in the second direction D2). The lower wiring pattern 112a may extend in a first direction D1 or a third direction D3. The lower wiring pattern 112a may be spaced apart in a second direction D2. The lower wiring via 112b may connect the lower wiring pattern 112a spaced apart in the second direction D2.

In some embodiments, the lower wiring line 112 may include a conductive material. For example, in an embodiment the lower wiring line 112 may include copper (Cu), aluminum (Al), silver (Ag), tin (Sn), gold (Au), nickel (Ni), lead (Pb), titanium (Ti), or an alloy thereof. However, embodiments of the present disclosure are not necessarily limited thereto.

In some embodiments, a lower wiring connection pad 115 may be disposed on an upper surface of the lower wiring structure 110 (e.g., disposed directly thereon in the second direction D2). The lower wiring connection pad 115 may be electrically connected to the lower wiring line 112 of the lower wiring structure 110.

FIG. 2 illustrates that the lower wiring connection pad 115 is disposed within a first mold layer 180. However, embodiments of the present disclosure are not necessarily limited thereto. For example, in an embodiment, the lower wiring connection pad 115 may be disposed within the lower insulation layer 111. In this embodiment, an upper surface of the lower wiring connection pad 115 may be disposed on an identical plane with an upper surface of the lower insulation layer 111.

In some embodiments, an external connection terminal 15 may be disposed on a lower surface of the lower wiring structure 110. The external connection terminal 15 may be attached to an external connection pad 10 (e.g., attached directly thereto). In an embodiment, the external connection terminal 15 may be a solder ball or a solder bump. The external connection terminal 15 may be, for example, a spherical shape or an ellipsoidal shape (e.g., in a cross-sectional view). However, embodiments of the present disclosure are not necessarily limited thereto.

In some embodiments, the external connection terminal 15 may electrically connect the lower wiring structure 110 to an external apparatus. Accordingly, the external connection terminal 15 may provide electrical signals to the lower wiring structure 110 or may provide an external apparatus with electrical signals provided from the lower wiring structure 110.

In some embodiments, the external connection terminal 15 may include, for example, at least one compound selected from tin (Sn), indium (In), lead (Pb), zinc (Zn), nickel (Ni), gold (Au), silver (Ag), copper (Cu), antimony (Sb), bismuth (Bi), and a combination thereof. However, embodiments of the present disclosure are not necessarily limited thereto.

In some embodiments, the first semiconductor chip 100 and the second semiconductor chip 200 may be disposed to be spaced apart from each other in the first direction D1. The first semiconductor chip 100 and the second semiconductor chip 200 may be disposed on the lower wiring structure 110. In the second direction D2, the first semiconductor chip 100 and the second semiconductor chip 200 may be disposed above the lower wiring structure 110. The second direction D2 may intersect the first direction D1. For example, in an embodiment, the second direction D2 may be perpendicular to the first direction D1. However, embodiments of the present disclosure are not necessarily limited thereto. In an embodiment, the first semiconductor chip 100 and the second semiconductor chip 200 may be flip-chip bonded on the lower wiring structure 110. FIG. 2 illustrates that the first semiconductor chip 100 and the second semiconductor chip 200 are flip-chip bonded on the lower wiring structure 110. However, embodiments of the present disclosure are not necessarily limited thereto. For example, in some embodiments the first semiconductor chip 100 and the second semiconductor chip 200 may be wire bonded on the lower wiring structure 110.

In some embodiments, each of the first semiconductor chip 100 and the second semiconductor chip 200 may be an integrated circuit (IC) in which hundreds to millions or more of semiconductor devices are integrated into one chip. For example, in an embodiment each of the first semiconductor chip 100 and the second semiconductor chip 200 may be an application processor (AP) chip such as a microprocessor and a microcontroller, a logic chip such as a central processing unit (CPU), a graphic processing unit (GPU), a modem, an application-specific IC (ASIC), and a field programmable gate array (FPGA), a volatile memory chip such as dynamic random access memory (DRAM) or static random access memory (SRAM), a non-volatile memory chip such as phase-change random access memory (PRAM), magnetoresistive random access memory (MRAM), ferroelectric random access memory (FeRAM), and resistive random access memory (RRAM), flash memory, or high bandwidth memory (HBM) or may include a combination thereof.

In some embodiments, the first semiconductor chip 100 and the second semiconductor chip 200 may be identical kind of semiconductor chips to each other. For example, both the first semiconductor chip 100 and the second semiconductor chip 200 may be a logic chip. However, embodiments of the present disclosure are not necessarily limited thereto, and the first semiconductor chip 100 and the second semiconductor chip 200 may also be semiconductor chips of different kinds from each other. For example, in an embodiment the first semiconductor chip 100 may be an AP chip or a logic chip, and the second semiconductor chip 200 may be a memory chip. Hereinafter, both the first semiconductor chip 100 and the second semiconductor chip 200 are described as including logic chips.

In some embodiments, each of the first semiconductor chip 100 and the second semiconductor chip 200 may include a substrate and a wiring structure. Each of the substrates of the first semiconductor chip 100 and the second semiconductor chip 200 may be a bulk silicon or a silicon-on-insulator (SOI). However, embodiments of the present disclosure are not necessarily limited thereto. For example, each of the first semiconductor chip 100 and the second semiconductor chip 200 may also be a silicon substrate or may also include other materials, for example, silicon germanium, silicon germanium on insulator (SGOI), indium antimonide, lead telluride, indium arsenide, indium phosphide, gallium arsenide, or gallium antimonide. Alternatively, each of the first semiconductor chip 100 and the second semiconductor chip 200 may be an epi-layer formed on a base substrate.

In some embodiments, the wiring structure of the first semiconductor chip 100 and the wiring structure of the second semiconductor chip 200 may be formed on the substrate of the first semiconductor chip 100 and the substrate of the second semiconductor chip 200, respectively. In an embodiment, each of the wiring structures of the first semiconductor chip 100 and the second semiconductor chip 200 may include multilayer wiring patterns and insulation layers for mutually insulating the multilayer wiring patterns.

In some embodiments, the first semiconductor chip 100 and the second semiconductor chip 200 may include a plurality of circuit elements. The plurality of circuit elements of the first semiconductor chip 100 and the second semiconductor chip 200 may be electrically connected to the lower wiring line 112 of the lower wiring structure 110.

In some embodiments, the first semiconductor chip 100 may be connected to the lower wiring structure 110 through a first connection bump 150 and a first connection pad 155. The first connection pad 155 may be disposed on (e.g., disposed directly thereon) a bottom surface of the first semiconductor chip 100. The first connection bump 150 may be disposed between the first connection pad 155 and the lower wiring connection pad 115 (e.g., in the second direction D2). The first connection bump 150 may be disposed on (e.g., disposed directly thereon) the lower wiring connection pad 115.

In some embodiments, the second semiconductor chip 200 may be connected to the lower wiring structure 110 through a second connection bump 250 and a second connection pad 255. The second connection pad 255 may be disposed on (e.g., disposed directly thereon) a bottom surface of the second semiconductor chip 200. The second connection bump 250 may be disposed between the second connection pad 255 and the lower wiring connection pad 115 (e.g., in the second direction D2). The second connection bump 250 may be disposed on (e.g., disposed directly thereon) the lower wiring connection pad 115.

In some embodiments, the first semiconductor chip 100 and the second semiconductor chip 200 may be symmetrically positioned based on the third semiconductor chip 300. For example, in an embodiment, in the first direction D1, the first semiconductor chip 100 and the second semiconductor chip 200 may be symmetrically positioned based on a central axis 300CT of the third semiconductor chip. Thus, the first semiconductor chip 100 and the second semiconductor chip 200 may be centered on the third semiconductor chip 300. A distance (e.g., length in the first direction D1) between an inner side surface 100IS of the first semiconductor chip and the central axis 300CT of the third semiconductor chip may be a first distance Dil. A distance (e.g., length in the first direction D1) between an inner side surface 200IS of the second semiconductor chip and the central axis 300CT of the third semiconductor chip may be a second distance Di2. In an embodiment, the first distance Di1 and the second distance Di2 may be identical to each other. Each of the inner side surface 100IS of the first semiconductor chip and the inner side surface 200IS of the second semiconductor chip may refer to a side surface closest to the central axis 300CT of the third semiconductor chip among side surfaces disposed at opposite sides to each other in the first direction D1 of the first semiconductor chip 100 and the second semiconductor chip 200.

In some embodiments, as the first semiconductor chip 100 and the second semiconductor chip 200 are symmetrically positioned based on the third semiconductor chip 300, a space may be secured for the heat transfer parts 400 to be disposed on the first semiconductor chip 100 and the second semiconductor chip 200. The heat dissipation performance of the semiconductor package may be increased using the heat transfer parts 400 disposed on the first semiconductor chip 100 and the second semiconductor chip 200.

In some embodiments, heat generated from the first semiconductor chip 100 and the second semiconductor chip 200 may be evenly dispersed through a symmetrical structure without concentrating on some areas. For example, when the first semiconductor chip 100 and the second semiconductor chip 200 are asymmetrically positioned based on the third semiconductor chip 300, heat generated from the first semiconductor chip 100 and the second semiconductor chip 200 may be concentrated on some areas within the semiconductor package. In contrast, in an embodiment in which the first semiconductor chip 100 and the second semiconductor chip 200 are symmetrically positioned based on the third semiconductor chip 300, heat generated from the first semiconductor chip 100 and the second semiconductor chip 200 may be evenly dispersed within the semiconductor package, which may alleviate a risk due to asymmetrical heat generation such as warpage of a package.

In some embodiments, the first mold layer 180 may surround the first semiconductor chip 100 and the second semiconductor chip 200. For example, in an embodiment the first mold layer 180 may surround a side surface of each of the first semiconductor chip 100 and the second semiconductor chip 200. The first semiconductor chip 100 and the second semiconductor chip 200 may be disposed within the first mold layer 180. The first mold layer 180 may surround the first connection bump 150, the first connection pad 155, the second connection bump 250, and the second connection pad 255.

In some embodiments, the first mold layer 180 may not cover upper surfaces of the first semiconductor chip 100 and the second semiconductor chip 200. For example, the upper surface of the first semiconductor chip 100 and the upper surface of the second semiconductor chip 200 may be exposed by the first mold layer 180.

For example, in an embodiment the first mold layer 180 may include an insulating polymer material such as epoxy molding compound (EMC). However, embodiments of the present disclosure are not necessarily limited thereto. In an embodiment, the first mold layer 180 may include a thermosetting resin such as epoxy resins, a thermoplastic resin such as polyimide, or a resin with reinforcements such as fillers included in the above resins, for example, ABF, FR-4, and BT resins.

In some embodiments, the upper wiring structure 120 may be disposed on the first semiconductor chip 100 and the second semiconductor chip 200. For example, in an embodiment the upper wiring structure 120 may be disposed directly on portions of the upper surface of the first semiconductor chip 100 and the second semiconductor chip 200. The upper wiring structure 120 may be disposed below the third semiconductor chip 300 (e.g., in the direction opposite to the second direction D2). In the first direction D1, the upper wiring structure 120 may be disposed between (e.g., directly therebetween) the heat transfer parts 400.

In some embodiments, the upper wiring structure 120 may be overlapped with at least a portion of the first semiconductor chip 100 and at least a portion of the second semiconductor chip 200 in the second direction D2. In an embodiment, a bottom surface of the upper wiring structure 120 may be in direct contact with at least a portion of the upper surface of the first semiconductor chip 100 and at least a portion of the upper surface of the second semiconductor chip 200. In this embodiment, the bottom surface of the upper wiring structure 120 may refer to a bottom surface of an upper insulation layer 121.

In some embodiments, the upper wiring structure 120 may be electrically connected to the third semiconductor chip 300.

In some embodiments, the upper wiring structure 120 may include the upper insulation layer 121 and an upper wiring line 122. The upper wiring line 122 may include a wiring pattern 122a extending in the first direction D1 and spaced apart in the second direction D2 and a wiring via 122b extending in the second direction D2 between the wiring pattern 122a spaced apart in the second direction D2 to electrically connect the wiring pattern 122a spaced apart in the second direction D2. The upper wiring line 122 of the upper wiring structure 120 may electrically connect the third semiconductor chip 300 and the wiring post 130 to each other. Descriptions about the upper insulation layer 121 and the upper wiring line 122 are substantially identical to the descriptions about the lower insulation layer 111 and the lower wiring line 112 and thus are omitted for economy of explanation.

In some embodiments, a width W120 (e.g., length in the first direction D1) of the upper wiring structure may be less than a width W110 (e.g., length in the first direction D1) of the lower wiring structure. The width W120 of the upper wiring structure may refer to the maximum width of the upper wiring structure 120 disposed between the heat transfer parts 400 in the first direction D1. For example, the width W120 of the upper wiring structure may refer to the width of the upper insulation layer 121 disposed between second portions 420 of the heat transfer parts 400 (e.g., in the first direction D1).

In some embodiments, an upper surface 120US of the upper wiring structure may be disposed on an identical plane (e.g., in the second direction D2) with an upper surface 400US of the heat transfer part. The upper surface 120US of the upper wiring structure may refer to an upper surface of the upper insulation layer 121. A bottom surface 120BS of the upper wiring structure may be disposed on an identical plane (e.g., in the second direction D2) with a bottom surface 400BS of the heat transfer part. The bottom surface 120BS of the upper wiring structure may refer to the bottom surface of the upper insulation layer 121. In an embodiment, in the second direction D2, a thickness TH120 of the upper wiring structure and a thickness TH400 of the heat transfer parts may be identical to each other. The thickness TH400 of the heat transfer parts may refer to a distance (e.g., in the second direction D2) between the upper surface 400US of the heat transfer parts and the bottom surface 400BS of the heat transfer part. In an embodiment, the thickness TH120 of the upper wiring structure and the thickness TH400 of the heat transfer parts which are identical in the second direction D2 may result from the upper wiring structure 120 and the heat transfer parts 400 which are formed through an identical fabricating stage. In this embodiment, since the heat transfer parts 400 is not formed through a separate fabrication process but formed together in a process in which the upper wiring structure 120 is formed, a fabrication process may be simplified.

In some embodiments, an upper wiring connection pad 125 may be disposed on the upper surface 120US of the upper wiring structure (e.g., disposed directly thereon in the second direction D2). The upper wiring connection pad 125 may be electrically connected to the upper wiring line 122 of the upper wiring structure 120.

FIG. 2 illustrates that the upper wiring connection pad 125 is disposed within a second mold layer 190. However, embodiments of the present disclosure are not necessarily limited thereto. For example, in an embodiment the upper wiring connection pad 125 may be disposed within the upper insulation layer 121. In an embodiment, an upper surface of the upper wiring connection pad 125 may be disposed on an identical plane (e.g., in the second direction D2) with the upper surface of the upper insulation layer 121.

In some embodiments, the wiring post 130 may be disposed on the lower wiring structure 110. The wiring post 130 may be disposed between the first semiconductor chip 100 and the second semiconductor chip 200 (e.g., in the second direction D2). The wiring post 130 may be disposed below the upper wiring structure 120 (e.g., in a direction opposite to the second direction D2). The wiring post 130 may be disposed on the lower wiring connection pad 115 (e.g., disposed directly thereon in the second direction D2). The wiring post 130 may be disposed within the first mold layer 180. The wiring post 130 may be surrounded by the first mold layer 180. The wiring post 130 may penetrate the first mold layer 180.

In some embodiments, the wiring post 130 may extend in the second direction D2. For example, the wiring post 130 may extend in the second direction D2 between the lower wiring structure 110 and the upper wiring structure 120. The wiring post 130 may electrically connect the lower wiring structure 110 and the upper wiring structure 120 to each other.

In some embodiments, the third semiconductor chip 300 may be disposed on the upper wiring structure 120 (e.g., in the second direction D2). The third semiconductor chip 300 may be disposed between the heat dissipation parts 500 (e.g., in the first direction D1). The third semiconductor chip 300 may be surrounded by the heat dissipation part 500. In an embodiment, the third semiconductor chip 300 may be spaced apart from the heat dissipation part 500 in the first direction D1 and the third direction D3. In an embodiment, the third semiconductor chip 300 may be flip-chip bonded on the upper wiring structure 120. However, embodiments of the present disclosure are not necessarily limited thereto. For example, in an embodiment the third semiconductor chip 300 may be wire bonded on the upper wiring structure 120.

In some embodiments, the third semiconductor chip 300 may be overlapped with the upper wiring structure 120 in the second direction D2. In an embodiment, a width W300 (e.g., length in the first direction D1) of the third semiconductor chip may be less than the width W120 (e.g., length in the first direction D1) of the upper wiring structure. The third semiconductor chip 300 may not be overlapped with the heat transfer parts 400 in the second direction D2. For example, since the width W300 of the third semiconductor chip is less than the width W120 of the upper wiring structure disposed between the heat transfer parts 400, the third semiconductor chip 300 and the heat transfer parts 400 may not overlap each other in the second direction D2.

In some embodiments, the third semiconductor chip 300 may be disposed in the middle of the first semiconductor chip 100 and the second semiconductor chip 200 in the first direction D1. For example, in the second direction D2, a width in which the third semiconductor chip 300 and the first semiconductor chip 100 are overlapped and a width in which the third semiconductor chip 300 and the second semiconductor chip 200 are overlapped may be identical to each other.

In some embodiments, the third semiconductor chip 300 may include a plurality of circuit elements. The plurality of circuit elements of the third semiconductor chip 300 may be electrically connected to the upper wiring line 122 of the upper wiring structure 120.

In some embodiments, the third semiconductor chip 300 may be an IC in which hundreds to millions or more of semiconductor devices are integrated into one chip. For example, in an embodiment the third semiconductor chip 300 may be an AP chip such as a microprocessor and a microcontroller, a logic chip such as a CPU, a GPU, a modem, an ASIC, and an FPGA, a volatile memory chip such as DRAM or SRAM, a non-volatile memory chip such as PRAM, MRAM, FeRAM, and RRAM, flash memory, or HBM or may include a combination thereof.

In some embodiments, the third semiconductor chip 300 may include a semiconductor chip of a different kind from the first semiconductor chip 100 and the second semiconductor chip 200. For example, in an embodiment each of the first semiconductor chip 100 and the second semiconductor chip 200 may be a memory chip, and the third semiconductor chip 300 may be a logic chip. However, embodiments of the present disclosure are not necessarily limited thereto, and the third semiconductor chip 300 may also be a semiconductor chip of an identical kind to the first semiconductor chip 100 and the second semiconductor chip 200. For example, in an embodiment all of the first semiconductor chip 100, the second semiconductor chip 200, and the third semiconductor chip 300 may include logic chips. Hereinafter, the third semiconductor chip 300 is described as including a memory chip.

In some embodiments, the third semiconductor chip 300 may be connected to the upper wiring structure 120 through a third connection bump 350 and a third connection pad 355. In an embodiment, the third connection pad 355 may be exposed by the bottom surface of the third semiconductor chip 300. The third connection bump 350 may be disposed between the third connection pad 355 and the upper wiring connection pad 125 (e.g., in the second direction D2). The third connection bump 350 may be disposed on the upper wiring connection pad 125 (e.g., disposed directly thereon in the second direction D2).

In some embodiments, the heat transfer parts 400 may be disposed on the first semiconductor chip 100 and the second semiconductor chip 200 (e.g., disposed directly thereon in the second direction D2). The bottom surface 400BS of the heat transfer parts may be in direct contact with the upper surface of the first semiconductor chip 100 and an upper surface 200US of the second semiconductor chip. At least a portion of the heat transfer parts 400 may be overlapped with the first semiconductor chip 100 and the second semiconductor chip 200 in the second direction D2. The heat transfer parts 400 may be disposed below the heat dissipation part 500 (e.g., in a direction opposite to the second direction D2).

In some embodiments, the heat transfer parts 400 may be spaced apart from each other in the first direction D1, having the upper wiring structure 120 therebetween. For example, the heat transfer parts 400 may be spaced apart from each other in the first direction D1, having the upper wiring line 122 of the upper wiring structure 120 therebetween. The heat transfer parts 400 may be spaced apart from the upper wiring line 122 of the upper wiring structure 120 in the first direction D1. The heat transfer parts 400 may be surrounded by a side insulation film 170. For example, a side surface of the heat transfer parts 400 may be covered by the side insulation film 170.

In some embodiments, based on the central axis 300CT of the third semiconductor chip in the first direction D1, the side insulation film 170 may be disposed at an outer side of the heat transfer parts 400. The side insulation film 170 may cover an outer side surface of the heat transfer parts 400. In an embodiment, the side insulation film 170 and the upper insulation layer 121 may include an identical material as each other.

In some embodiments, the heat transfer parts 400 may not be uniform in width from each other in the first direction D1. In an embodiment, the heat transfer parts 400 may include a plurality of layers that are different from each other. For example, the heat transfer parts 400 may include a first portion 410 and the second portion 420 which are different in width from each other in the first direction D1. In an embodiment, the first portion 410 and the second portion 420 may be alternately stacked in the second direction D2. In an embodiment, a width W410 of the first portion (e.g., in the first direction D1) may be greater than a width W420 of the second portion (e.g., in the first direction D1).

In some embodiments, the first portion 410 may be disposed at an identical level with the upper wiring pattern 122a in the second direction D2. The second portion 420 may be disposed at an identical level with the upper wiring via 122b in the second direction D2.

In some embodiments, being disposed at an identical level may refer to being formed at an identical fabricating stage. For example, in an embodiment the first portion 410 may be formed at an identical fabricating stage with the upper wiring pattern 122a. The second portion 420 may be formed at an identical fabricating stage with the upper wiring via 122b.

In some embodiments, being disposed at an identical level may refer to an upper surface or a bottom surface of each configuration being disposed on an identical plane in the second direction D2. For example, an upper surface or a bottom surface of the first portion 410 may be disposed on an identical plane with an upper surface or a bottom surface of the upper wiring pattern 122a. An upper surface or a bottom surface of the second portion 420 may be disposed on an identical plane with an upper surface or a bottom surface of the upper wiring via 122b.

In some embodiments, in the first direction D1, the width of the heat transfer parts 400 may be greater than the maximum length in which the upper wiring pattern 122a extends in the first direction D1. For example, the width W420 (e.g., length in the first direction D1) of the second portion of the heat transfer parts 400 may be greater than the maximum length in which the upper wiring pattern 122a extends in the first direction D1.

In some embodiments, the heat transfer parts 400 and the upper wiring line 122 may include an identical material as each other. For example, the heat transfer parts 400 may include a conductive material. In an embodiment, the heat transfer parts 400 may include copper (Cu), aluminum (Al), silver (Ag), tin (Sn), gold (Au), nickel (Ni), lead (Pb), titanium (Ti), or an alloy thereof. However, embodiments of the present disclosure are not necessarily limited thereto.

In some embodiments, the heat dissipation part 500 may be disposed on (e.g., disposed directly thereon) the heat transfer parts 400 in the second direction D2. At least a portion of the heat dissipation part 500 may be overlapped with the first semiconductor chip 100 and the second semiconductor chip 200 in the second direction D2. The heat dissipation part 500 may surround the third semiconductor chip 300. In the first direction D1, the heat dissipation part 500 may be spaced apart from the third semiconductor chip 300. In an embodiment, in the second direction D2 with respect to the upper surface of the lower wiring structure 110, an upper surface 500US of the heat dissipation part may be disposed above an upper surface 300US of the third semiconductor chip.

In some embodiments, in the first direction D1, the heat dissipation parts 500 may be symmetrically positioned based on the central axis 300CT of the third semiconductor chip. Thus, the heat dissipation parts 500 may be centered on the third semiconductor chip. For example, a distance (e.g., length in the first direction D1) between an inner side surface of the heat dissipation part 500 disposed on the first semiconductor chip 100 and the third semiconductor chip 300 may be identical to a distance (e.g., length in the first direction D1) between an inner side surface of the heat dissipation part 500 disposed on the second semiconductor chip 200 and the third semiconductor chip 300.

In some embodiments, the heat dissipation part 500 may have thermal conductivity. For example, in an embodiment the heat dissipation part 500 may include Cu—W, Cu—Mo, CMC (Cu/Mo/Cu), CPC (Cu/MoCu/Cu), SCMC, WCu, and CuC. However, embodiments of the present disclosure are not necessarily limited thereto. For example, in an embodiment the heat dissipation part 500 may include a metal such as copper (Cu) and aluminum (Al) or a material containing carbon such as graphene, graphite, and carbon nanotubes. The heat dissipation part 500 may dissipate heat generated from the first semiconductor chip 100 and the second semiconductor chip 200 after being transferred through the heat transfer parts 400.

In some embodiments, a thermally conductive layer 550 may be disposed between the heat transfer parts 400 and the heat dissipation part 500 (e.g., in the second direction D2). The thermally conductive layer 550 may be disposed on the heat transfer parts 400. The thermally conductive layer 550 may be disposed below the heat dissipation part 500 (e.g., in a direction opposite to the second direction D2). The thermally conductive layer 550 may include a thermally conductive and electrically insulating material. For example, in an embodiment the thermally conductive layer 550 may include a polymer including metal powder such as silver or copper, thermal grease, white grease, or a combination thereof.

FIGS. 2 and 3 illustrate that the thermally conductive layer 550 is disposed between the heat transfer parts 400 and the heat dissipation part 500 (e.g., in the second direction D2). However, embodiments of the present disclosure are not necessarily limited thereto. For example, in some embodiments the thermally conductive layer 550 may not be disposed between the heat transfer parts 400 and the heat dissipation part 500 (e.g., in the second direction D2). In this embodiment, the heat transfer parts 400 and the heat dissipation part 500 may be in direct contact with each other.

In some embodiments, the second mold layer 190 may surround the third semiconductor chip 300 and the heat dissipation part 500. The second mold layer 190 may be disposed on the upper wiring structure 120 and the heat transfer parts 400 (e.g., disposed directly thereon in the second direction D2). The second mold layer 190 may fill a space between the third semiconductor chip 300 and the heat dissipation part 500 which are spaced apart from each other. The second mold layer 190 may cover the third semiconductor chip 300 and the heat dissipation part 500. The second mold layer 190 may cover a side surface of each of the third semiconductor chip 300 and the heat dissipation part 500. The second mold layer 190 may surround the third connection bump 350 and the third connection pad 355. In an embodiment, an upper surface of the heat dissipation part 500 may be exposed by the second mold layer 190.

For example, in an embodiment the second mold layer 190 may include an insulating polymer material such as EMC. However, embodiments of the present disclosure are not necessarily limited thereto. In an embodiment, the second mold layer 190 may include a thermosetting resin such as epoxy resins, a thermoplastic resin such as polyimide, or a resin with reinforcements such as fillers included in the above resins, for example, ABF, FR-4, and BT resins.

In some embodiments, the first semiconductor chip 100 and the second semiconductor chip 200 may include semiconductor chips of a different kind from the third semiconductor chip 300. In an embodiment, the first semiconductor chip 100 and the second semiconductor chip 200 may include an identical kind of semiconductor chips as each other. In this embodiment, the amounts of heat generation of the first semiconductor chip 100 and the second semiconductor chip 200 may be different from the amount of heat generation of the third semiconductor chip 300. Through a structure of the first semiconductor chip 100 and the second semiconductor chip 200 that are symmetrically positioned based on the third semiconductor chip 300, a risk according to asymmetrical heat generation within a semiconductor package may be reduced or prevented.

In some embodiments, the first semiconductor chip 100 and the second semiconductor chip 200 may have an amount of heat generation greater than that of the third semiconductor chip 300. Through the heat transfer parts 400 and the heat dissipation part 500 that are disposed above the first semiconductor chip 100 and the second semiconductor chip 200, heat generated from the first semiconductor chip 100 and the second semiconductor chip 200 may be easily dissipated.

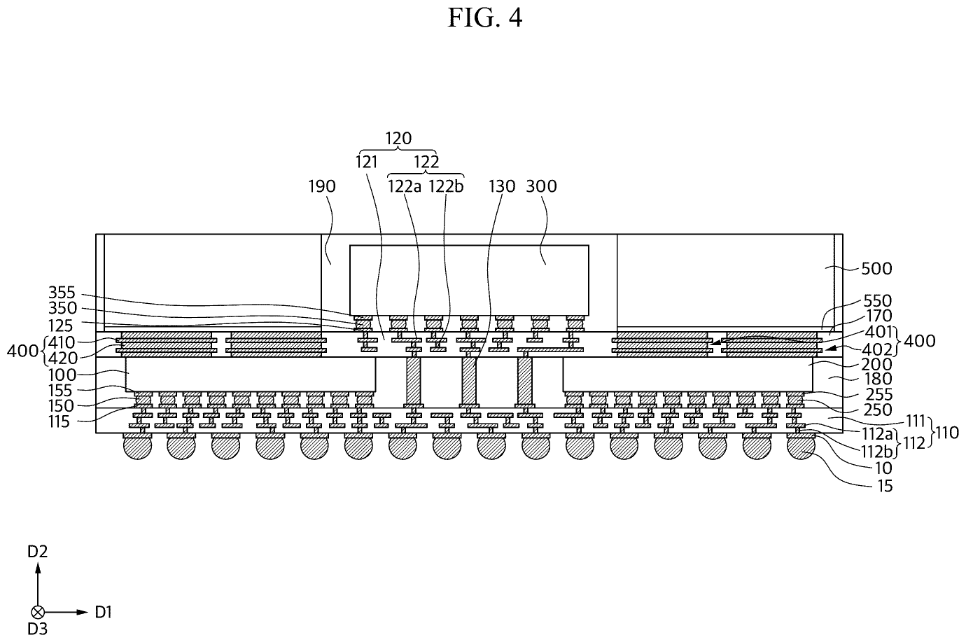

FIG. 4 is a cross-sectional view for illustrating a semiconductor package according to an embodiment. For convenience of description, differences from the descriptions with reference to FIGS. 1 to 3 are mainly described and a repeated description of similar or identical elements may be omitted for economy of explanation.

Referring to FIG. 4, in an embodiment each of the heat transfer parts 400 may include a plurality of heat transfer units. For example, in an embodiment each of the heat transfer parts 400 may include a first heat transfer unit 401 and a second heat transfer unit 402. The first heat transfer unit 401 and the second heat transfer unit 402 may be spaced apart from each other in the first direction D1. Each of the first heat transfer unit 401 and the second heat transfer unit 402 may be disposed on (e.g., disposed directly thereon in the second direction D2) the first semiconductor chip 100 and the second semiconductor chip 200.

Each of the first heat transfer unit 401 and the second heat transfer unit 402 may include the first portion 410 and the second portion 420. In an embodiment, in the first direction D1, the width of each of the first heat transfer unit 401 and the second heat transfer unit 402 may be greater than the maximum length in which the upper wiring pattern 122a extends in the first direction D1.

FIG. 4 illustrates that the plurality of heat transfer units included in each of the heat transfer parts 400 includes the first heat transfer unit 401 and the second heat transfer unit 402. However, embodiments of the present disclosure are not necessarily limited thereto and the number of heat transfer units may vary. For example, in an embodiment each of the heat transfer parts 400 may include three or more of the plurality of heat transfer units spaced apart from each other in the first direction D1. The number or shape of the plurality of heat transfer units included in each of the heat transfer parts 400 may be variously changed.

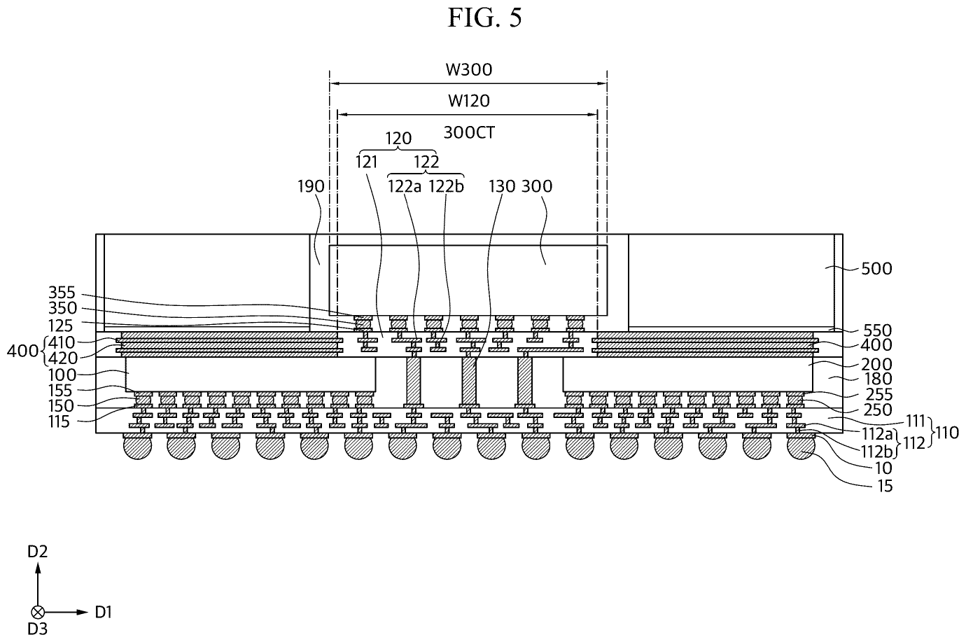

FIGS. 5 to 10 are cross-sectional views for illustrating a semiconductor package according to an embodiment. For convenience of description, differences from the descriptions with reference to FIGS. 1 to 4 are mainly described and a repeated description of similar or identical elements may be omitted for economy of explanation.

Referring to FIG. 5, in an embodiment the width W300 (e.g., length in the first direction D1) of the third semiconductor chip may be greater than the width W120 (e.g., length in the first direction D1) of the upper wiring structure. At least a portion of the third semiconductor chip 300 may be overlapped with the heat transfer parts 400 in the second direction D2.

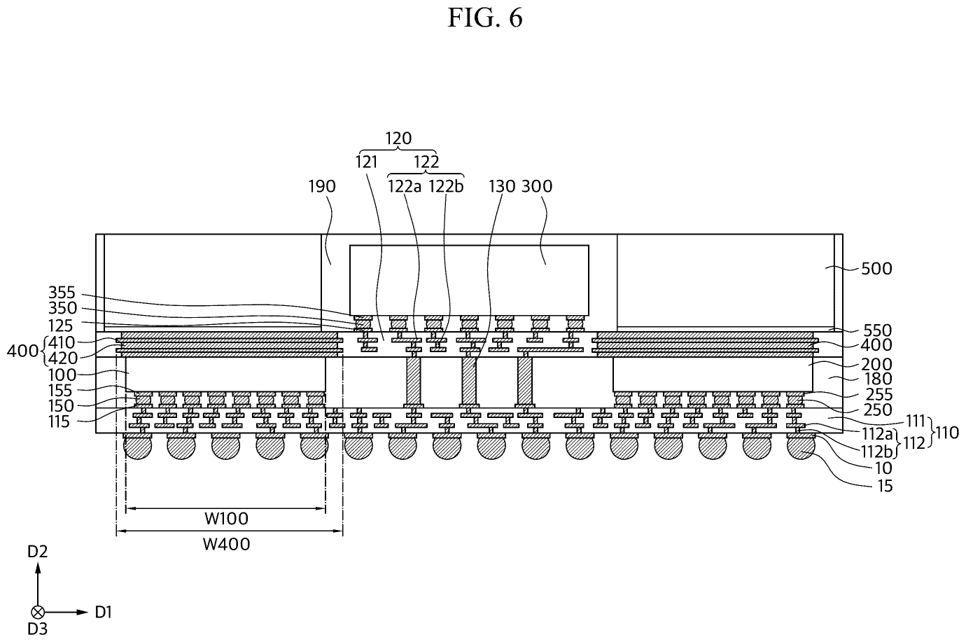

Referring to FIG. 6, in an embodiment each of the first semiconductor chip 100 and the second semiconductor chip 200 may be completely overlapped with the heat transfer parts 400 in the second direction D2. For example, a width W100 (e.g., length in the first direction D1) of the first semiconductor chip may be less than a width W400 (e.g., length in the first direction D1) of the heat transfer part. The heat transfer parts 400 may cover the whole of the upper surface of the first semiconductor chip 100 and the upper surface of the second semiconductor chip 200. Compared to the surface areas of the first semiconductor chip 100 and the second semiconductor chip 200, the area in which the heat transfer parts 400 is in direct contact with the first semiconductor chip 100 and the second semiconductor chip 200 increases, which thus may increase the efficiency of emitting heat generated from the first semiconductor chip 100 and the second semiconductor chip 200 through the heat transfer parts 400 and the heat dissipation part 500.

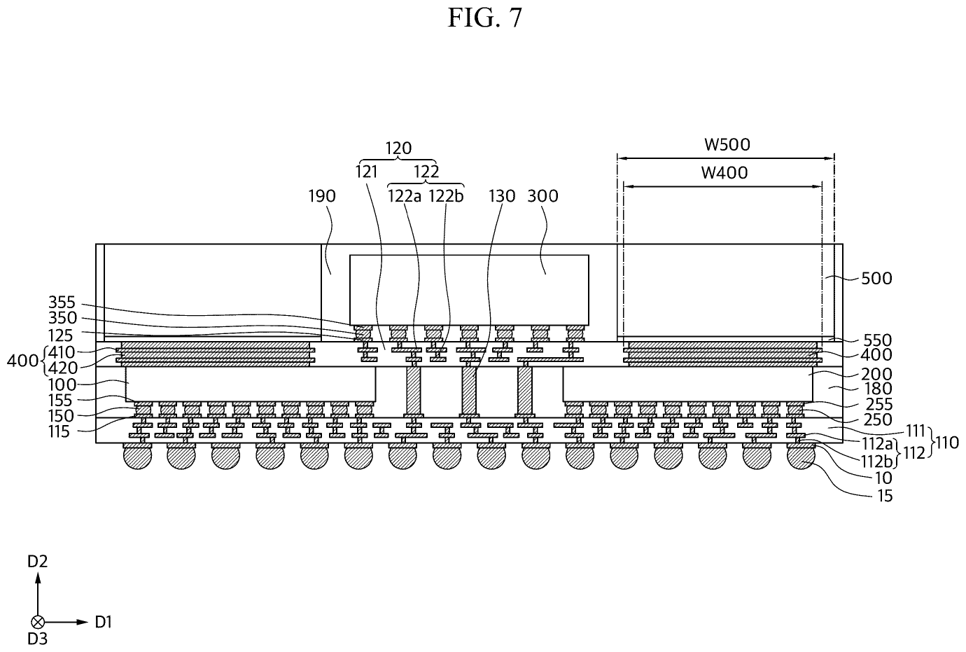

Referring to FIG. 7, the heat transfer parts 400 may be completely overlapped with the heat dissipation part 500 in the second direction D2. For example, the width W400 (e.g., length in the first direction D1) of the heat transfer parts 400 may be less than a width W500 (e.g., length in the first direction D1) of the heat dissipation part 500. Since the heat transfer parts 400 is completely overlapped with the heat dissipation part 500 in the second direction D2, heat generated from the first semiconductor chip 100 and the second semiconductor chip 200 may be prevented from being transferred to the third semiconductor chip 300 and may be stably emitted through the heat transfer parts 400 and the heat dissipation part 500 to the outside (e.g., the external environment).

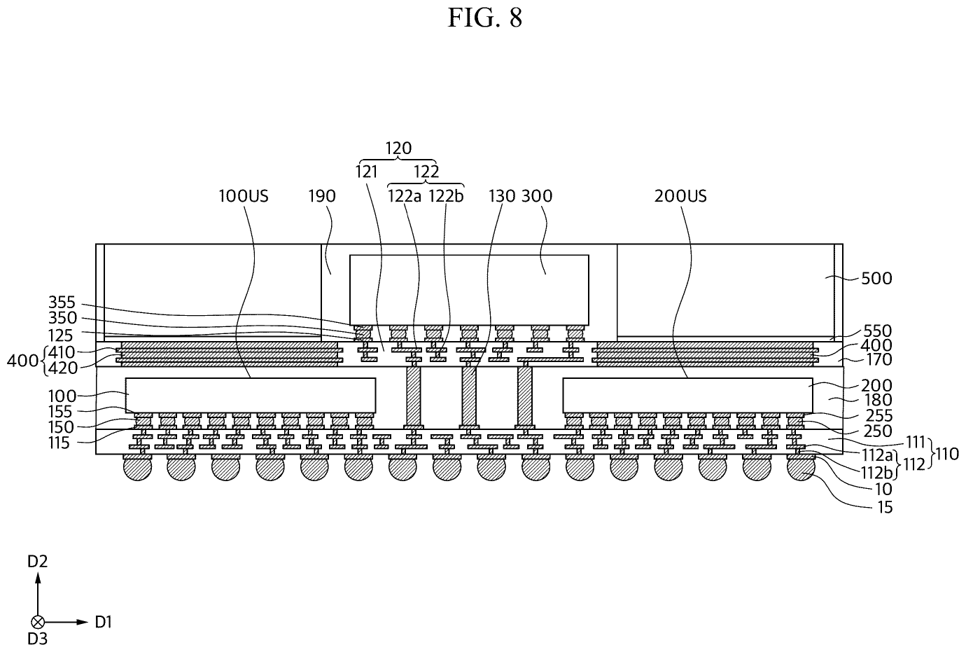

Referring to FIG. 8, the first mold layer 180 may cover an upper surface 100US of the first semiconductor chip and the upper surface 200US of the second semiconductor chip. For example, in an embodiment the first mold layer 180 may cover entireties of an upper surface 100US of the first semiconductor chip and the upper surface 200US of the second semiconductor chip. Therefore, the first semiconductor chip 100 and the second semiconductor chip 200 may not be in direct contact with the heat transfer parts 400. The first mold layer 180 may be disposed between the first semiconductor chip 100 and the second semiconductor chip 200 and the heat dissipation part 500 (e.g., in the second direction D2). The first mold layer 180 may fill space between the upper surface 100US of the first semiconductor chip and a bottom surface of the heat transfer parts 400 which are spaced apart in the second direction D2 and space between the upper surface 200US of the second semiconductor chip and the bottom surface of the heat transfer parts 400 which are spaced apart in the second direction D2. Since a distance between the heat transfer parts 400 and the wiring post 130 increases, the electrical interference of the heat transfer parts 400 on the wiring post 130 may be reduced. Further, the first semiconductor chip 100 and the second semiconductor chip 200 may be bonded more stably on the lower wiring structure 110.

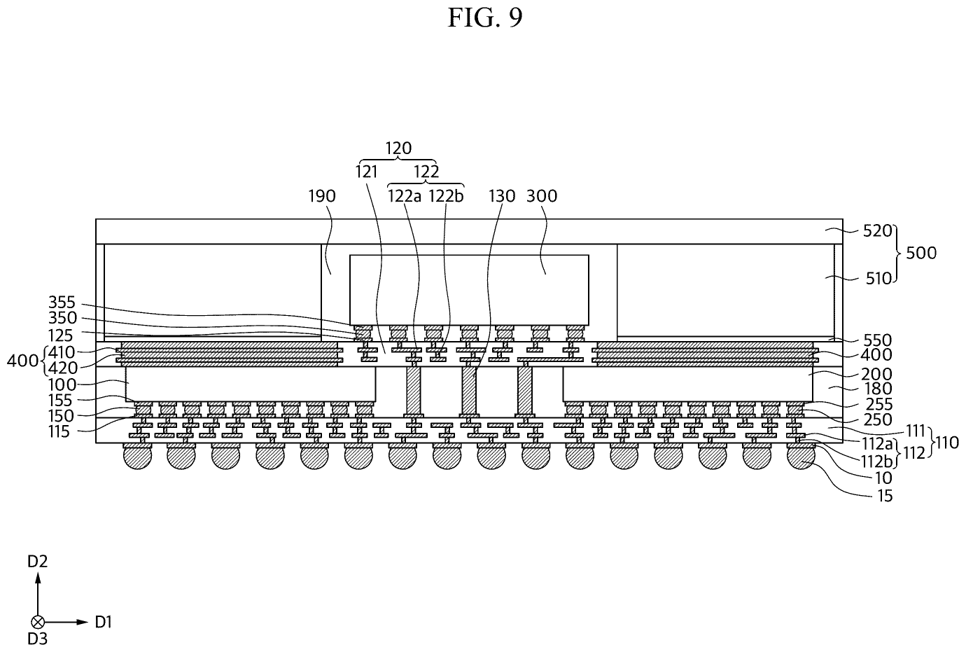

Referring to FIG. 9, in an embodiment the heat dissipation part 500 may include a first heat dissipation part 510 and a second dissipation part 520. The first heat dissipation part 510 may be spaced apart from the third semiconductor chip 300 in the first direction D1. At least a portion of the first heat dissipation part 510 may be overlapped with the third semiconductor chip 300 in the first direction D1. The first heat dissipation part 510 may surround the side surface of the third semiconductor chip 300.

In some embodiments, the second dissipation part 520 may be disposed on the third semiconductor chip 300 and the first dissipation part 510 (e.g., in the second direction D2). For example, in an embodiment the second dissipation part 520 may cover an upper surface of the third semiconductor chip 300 and an upper surface of the first dissipation part 510 (e.g., in the second direction D2). The second dissipation part 520 may be disposed on the second mold layer 190 (e.g., disposed directly thereon in the second direction D2). The second dissipation part 520 may extend in the first direction D1.

For example, the second dissipation part 520 may emit the heat generated from the first semiconductor chip 100 and the second semiconductor chip 200 after being transferred through the heat transfer parts 400 to the outside (e.g., the external environment). In addition, the second dissipation part 520 may emit the heat generated from the third semiconductor chip 300 to the outside (e.g., the external environment) after being directly transferred or transferred through the heat transfer parts 400.

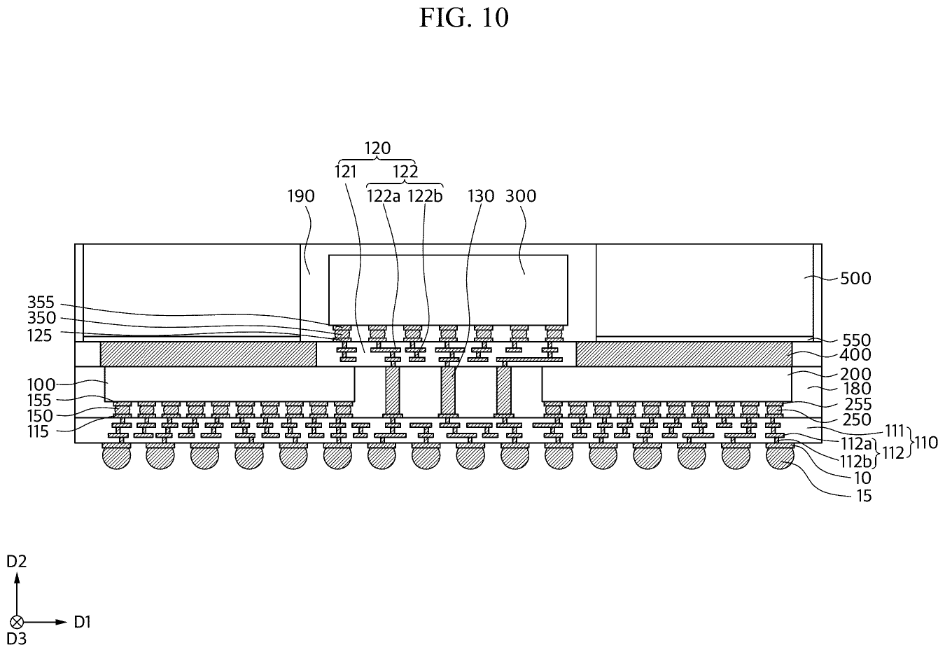

Referring to FIG. 10, the width of the heat transfer parts 400 may be uniform in the first direction D1. For example, the side surfaces of the heat transfer parts 400 disposed to be opposite to each other in the first direction D1 may have a plane shape without protruding in the first direction D1. For example, the side surfaces of the heat transfer parts 400 may extend linearly in the second direction D2.

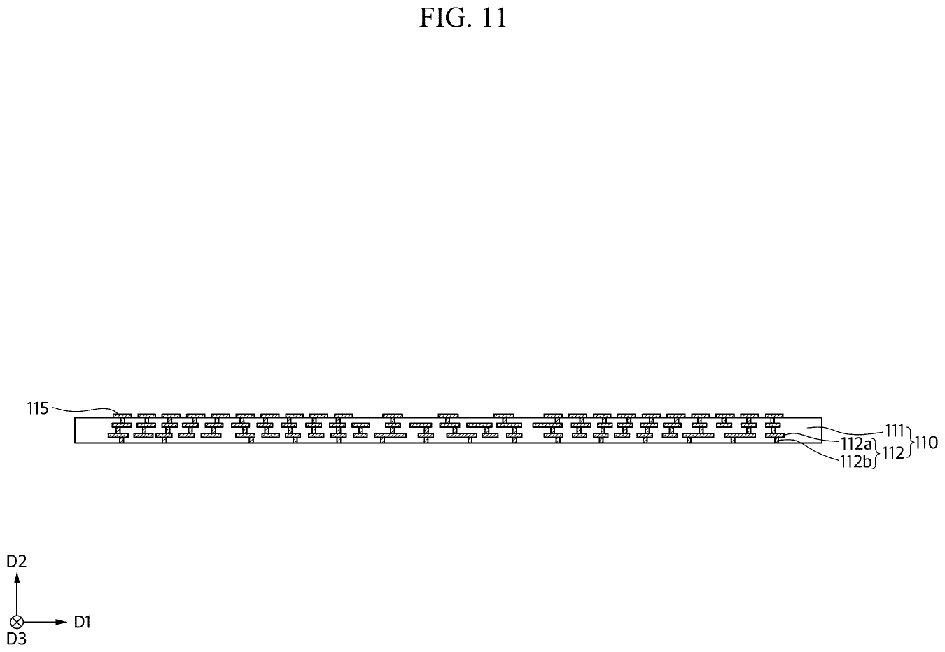

FIGS. 11 to 16 are diagrams of intermediate stages for illustrating a fabrication method of a semiconductor package according to embodiments of the present disclosure. For reference, FIGS. 11 to 16 illustrate a method of fabricating the semiconductor package illustrated in FIG. 2. For convenience of description, differences from the descriptions with reference to FIGS. 1 to 3 are mainly described and a repeated description of similar or identical elements may be omitted for economy of explanation.

Referring to FIG. 11, the lower wiring structure 110 and the lower wiring connection pad 115 may be formed. The lower wiring structure 110 may have the lower wiring line 112 formed within the lower insulation layer 111. The lower wiring connection pad 115 may be disposed on the lower wiring structure 110. In an embodiment, the lower wiring connection pad 115 may be disposed directly on an upper surface of the lower wiring structure 110 (e.g., in the second direction D2). For example, the lower wiring connection pad 115 may be disposed on (e.g., disposed directly thereon) the lower wiring structure 110 to be connected to the lower wiring line 112.

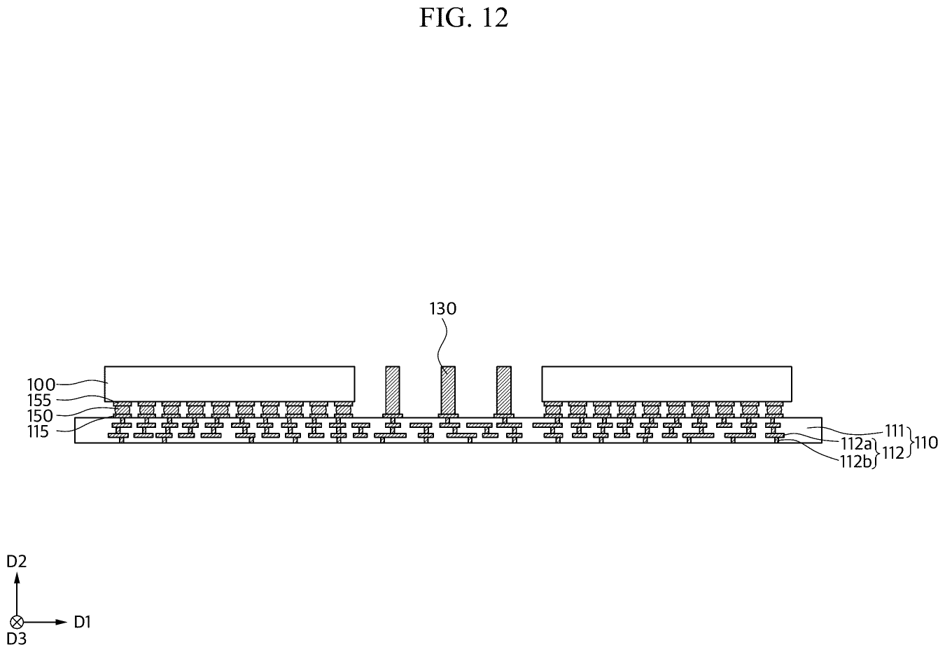

Referring to FIG. 12, the wiring post 130, the first semiconductor chip 100, and the second semiconductor chip 200 may then be formed on the lower wiring structure 110 (e.g., in the second direction D2). For example, in an embodiment the wiring post 130 may be formed first on the lower wiring connection pad 115. The first semiconductor chip 100 and the second semiconductor chip 200 may then be positioned symmetrically based on the wiring post 130 after the wiring post 130 is formed.

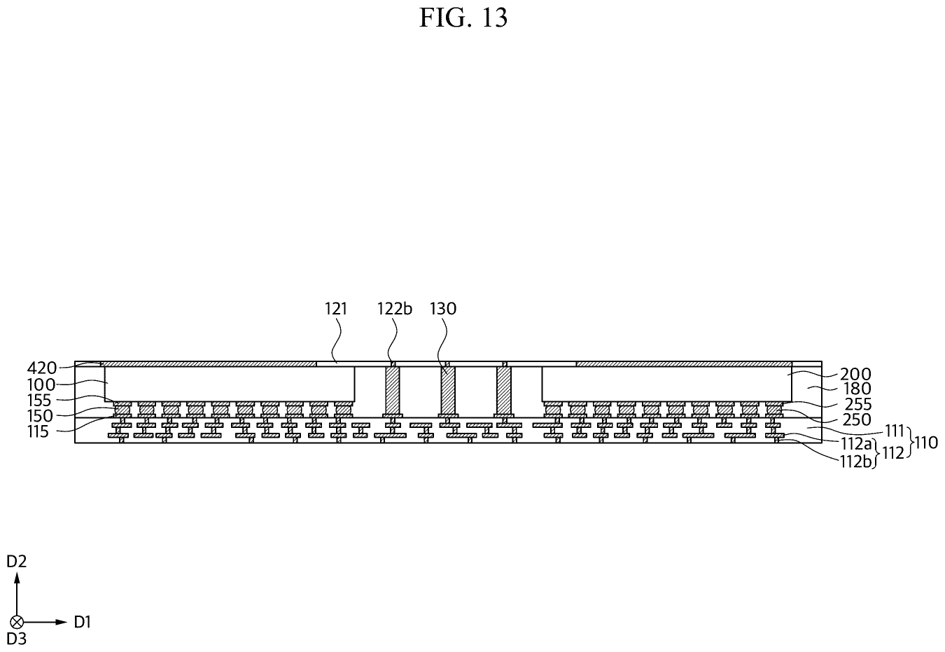

Referring to FIG. 13, the upper wiring via 122b of the upper wiring structure 120 of FIG. 2 and the second portion 420 of the heat transfer parts 400 of FIG. 2 may the be formed. The upper wiring via 122b may be disposed within the upper insulation layer 121. In an embodiment, when the upper wiring via 122b and the second portion 420 are formed, the upper insulation layer 121 may be formed together. For example, after the upper wiring via 122b and the second portion 420 are formed, the upper insulation layer 121 may then be formed. However, embodiments of the present disclosure are not necessarily limited thereto. For example, in an embodiment, after the upper insulation layer 121 is formed, the upper wiring via 122b may then be formed within a trench where a portion of the upper insulation layer 121 is removed.

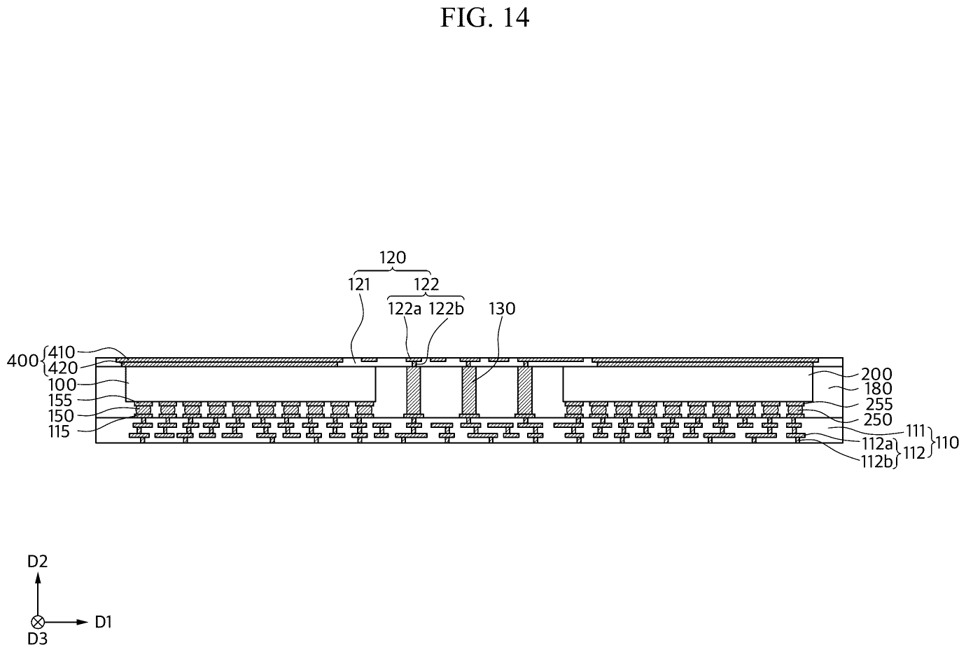

Referring to FIG. 14, the upper wiring pattern 122a of the upper wiring structure 120 and the first portion 410 of the heat transfer parts 400 may then be formed. The upper wiring pattern 122a may be formed on the upper wiring via 122b (e.g., formed directly thereon in the second direction D2). The first portion 410 may be formed on the second portion 420 (e.g., formed directly thereon in the second direction D2).

FIGS. 13 and 14 illustrate that the upper wiring via 122b of the upper wiring structure 120 of FIG. 2 and the second portion 420 are formed first. However, embodiments of the present disclosure are not necessarily limited thereto. For example, in an embodiment the upper wiring pattern 122a and the first portion 410 may be formed first.

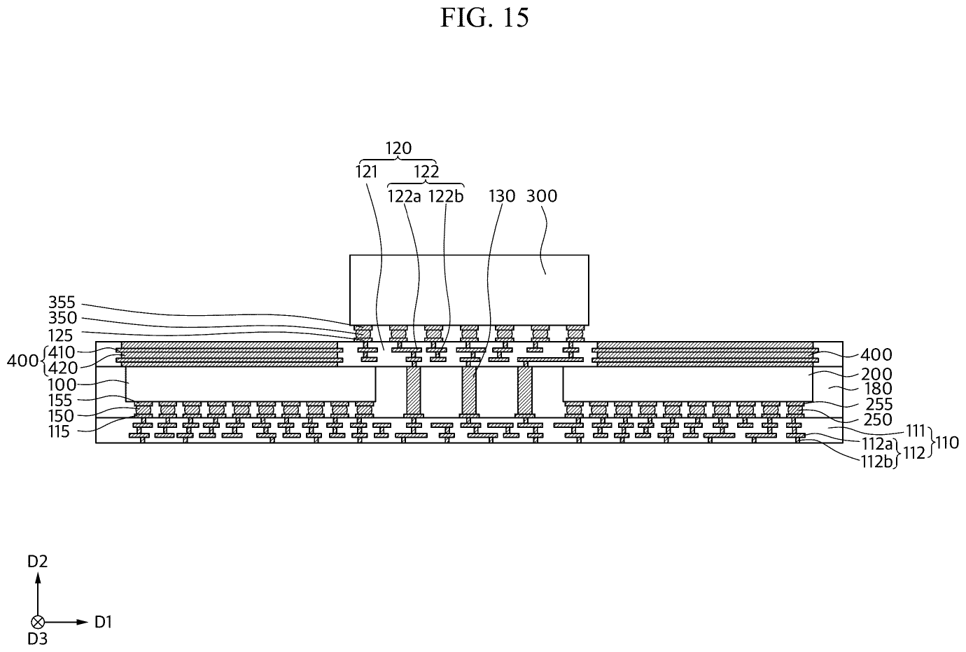

Referring to FIG. 15, the third semiconductor chip 300 may then be formed on the upper wiring structure 120 (e.g., in the second direction D2). The third semiconductor chip 300 may be disposed in the middle of the first semiconductor chip 100 and the second semiconductor chip 200 in the first direction D1. The third semiconductor chip 300 may be disposed in the middle of the heat transfer parts 400 in the first direction D1.

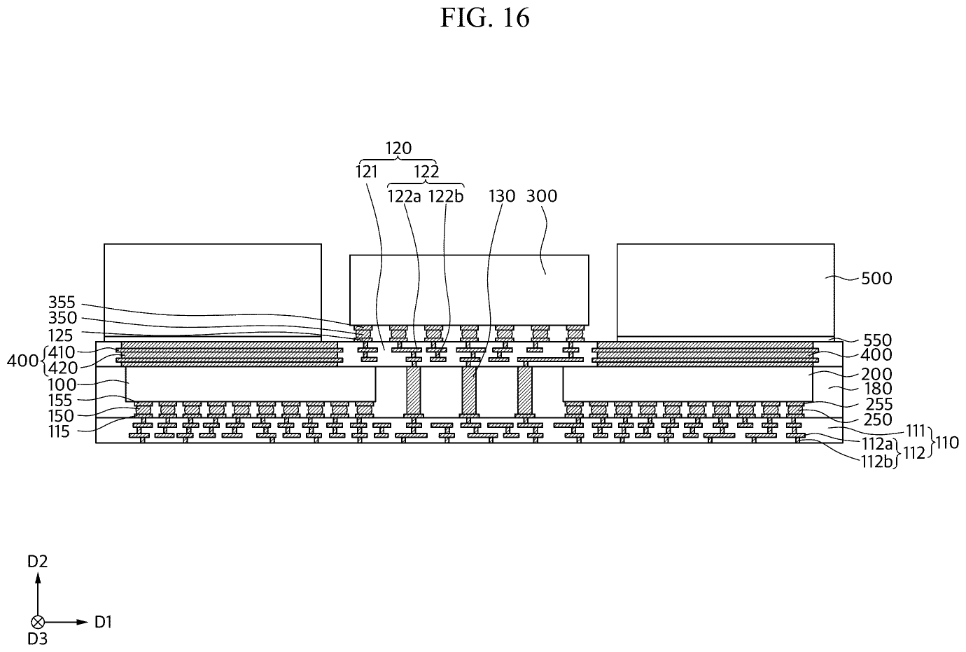

In an embodiment, referring to FIG. 16, the thermally conductive layer 550 and the heat dissipation part 500 may then be formed. The thermally conductive layer 550 and the heat dissipation part 500 may be spaced apart from the third semiconductor chip 300 (e.g., in the first direction D1) and formed to surround the side surface of the third semiconductor chip 300 (e.g., in the first direction D1). The thermally conductive layer 550 and the heat dissipation part 500 may be formed on the heat transfer parts 400 (e.g., formed directly thereon in the second direction D2).

Referring to FIG. 2, the second mold layer 190 which fills space between the third semiconductor chip 300 and the heat dissipation part 500 may then be formed. The external connection pad 10 and the external connection terminal 15 may be formed on a bottom surface of the lower wiring structure 110.

While various non-limiting embodiments of the present disclosure are described in detail above, embodiments of the present disclosure are not limited thereto, and it will be apparent to those skilled in the art that modifications and variations may be made without departing from the scope of the present disclosure. In addition, the aforementioned embodiments may be implemented with some elements removed, and each embodiment may be implemented in combination with each other.

What is claimed is:

1. A semiconductor package comprising:
a first semiconductor chip and a second semiconductor chip spaced apart from each other in a first direction;
heat transfer parts disposed on each of the first semiconductor chip and the second semiconductor chip in a second direction intersecting the first direction;
an upper wiring structure disposed between the heat transfer parts in the first direction; and
a third semiconductor chip disposed on the upper wiring structure in the second direction, the third semiconductor chip is electrically connected to the upper wiring structure,
wherein a thickness of the upper wiring structure in the second direction and a thickness of the heat transfer parts in the second direction are identical to each other.

2. The semiconductor package of claim 1, further comprising:
a lower wiring structure disposed below the first semiconductor chip and the second semiconductor chip in a direction opposite to the second direction; and
a wiring post disposed between the first semiconductor chip and the second semiconductor chip in the first direction, the wiring post electrically connecting the upper wiring structure and the lower wiring structure to each other.

3. The semiconductor package of claim 2, wherein a width of the upper wiring structure in the first direction is less than a width of the lower wiring structure in the first direction.

4. The semiconductor package of claim 2, wherein the first semiconductor chip and the second semiconductor chip are flip-chip bonded on the lower wiring structure.

5. The semiconductor package of claim 1, wherein the upper wiring structure overlaps a portion of the first semiconductor chip and a portion of the second semiconductor chip in the second direction.

6. The semiconductor package of claim 1, wherein:
the heat transfer parts includes a first portion and a second portion alternately stacked in the second direction,
wherein the upper wiring structure includes a wiring pattern extending in the first direction and spaced apart in the second direction and a wiring via electrically connecting the wiring pattern spaced apart in the second direction,
wherein a width of the first portion in the first direction is greater than a width of the second portion in the first direction, and
wherein, in the second direction, the first portion is disposed at a level identical to a level of the wiring pattern, and in the second direction, the second portion is disposed at a level identical to a level of the wiring via.

7. The semiconductor package of claim 1, wherein the first semiconductor chip and the second semiconductor chip are symmetrically positioned and centered on the third semiconductor chip in the first direction.

8. The semiconductor package of claim 1, wherein:
the upper wiring structure includes an upper wiring line electrically connected to the third semiconductor chip, and
wherein the upper wiring line is spaced apart from the heat transfer parts in the first direction.

9. The semiconductor package of claim 8, wherein:
the upper wiring line includes an upper wiring pattern extending in the first direction and spaced apart in the second direction and an upper wiring via electrically connecting the upper wiring pattern spaced apart in the second direction, and
wherein, in the first direction, a maximum length that the upper wiring pattern extends is less than a width of each of the heat transfer parts.

10. The semiconductor package of claim 8, wherein the heat transfer parts and the upper wiring line include an identical material as each other.

11. The semiconductor package of claim 1, further comprising a heat dissipation part spaced apart from the third semiconductor chip in the first direction, the heat dissipation part is disposed on the heat transfer parts in the second direction.

12. The semiconductor package of claim 11, wherein, in the second direction, an upper surface of the heat dissipation part is disposed above an upper surface of the third semiconductor chip.

13. The semiconductor package of claim 1, wherein:
each of the first semiconductor chip and the second semiconductor chip includes a logic chip; and
the third semiconductor chip includes a memory chip.

14. A semiconductor package comprising:
a first semiconductor chip and a second semiconductor chip spaced apart from each other in a first direction;
heat transfer parts disposed on each of the first semiconductor chip and the second semiconductor chip in a second direction intersecting the first direction;
an upper wiring structure disposed between the heat transfer parts in the first direction;
a wiring post disposed between the first semiconductor chip and the second semiconductor chip and positioned below the upper wiring structure in a direction opposite to the second direction, the wiring post is electrically connected to the upper wiring structure; and
a third semiconductor chip disposed on the upper wiring structure in the second direction, the third semiconductor chip is electrically connected to the upper wiring structure,
wherein a bottom surface of the heat transfer parts is in direct contact with an upper surface of the first semiconductor chip and an upper surface of the second semiconductor chip, and
wherein, in the first direction, a distance between a central axis of the third semiconductor chip and an inner side surface of the first semiconductor chip is identical to a distance between the central axis of the third semiconductor chip and an inner side surface of the second semiconductor chip.

15. The semiconductor package of claim 14, further comprising a heat dissipation part spaced apart from the third semiconductor chip in the first direction and disposed on the heat transfer parts in the second direction,
wherein the heat dissipation part is symmetrically positioned and centered on the third semiconductor chip in the first direction.

16. The semiconductor package of claim 15, further comprising a mold layer disposed on the upper wiring structure and the heat transfer parts, the mold layer covering the third semiconductor chip and the heat dissipation part.

17. The semiconductor package of claim 14, wherein the heat transfer parts include a plurality of layers.

18. The semiconductor package of claim 14, wherein the upper wiring structure includes an upper insulation layer filling space between the heat transfer parts in the first direction and an upper wiring line disposed within the upper insulation layer, the upper wiring line electrically connected to the third semiconductor chip, and
wherein an upper surface of the upper insulation layer is disposed on an identical plane in the second direction with an upper surface of the heat transfer parts.

19. The semiconductor package of claim 14, wherein, in the first direction, a distance between the central axis of the third semiconductor chip and an inner side surface of the heat transfer parts on the first semiconductor chip is identical to a distance between the central axis of the third semiconductor chip and an inner side surface of the heat transfer parts on the second semiconductor chip.

20. A semiconductor package comprising:
a first semiconductor chip and a second semiconductor chip spaced apart from each other in a first direction;
heat transfer parts disposed on each of the first semiconductor chip and the second semiconductor chip in a second direction intersecting the first direction;
an upper wiring structure disposed between the heat transfer parts in the first direction;
a third semiconductor chip disposed on the upper wiring structure in the second direction, the third semiconductor chip is electrically connected to the upper wiring structure;
a lower wiring structure disposed below the first semiconductor chip and the second semiconductor chip in a direction opposite to the second direction;
a wiring post disposed between the first semiconductor chip and the second semiconductor chip in the first direction, the wiring post electrically connecting the upper wiring structure and the lower wiring structure to each other; and
a heat dissipation part spaced apart from the third semiconductor chip in the first direction, the heat dissipation part is disposed on the heat transfer parts in the second direction,
wherein a bottom surface of the heat transfer parts is in direct contact with an upper surface of the first semiconductor chip and an upper surface of the second semiconductor chip,
wherein, in the first direction, the first semiconductor chip and the second semiconductor chip are symmetrically positioned based on a central axis of the third semiconductor chip,
wherein each of the first semiconductor chip and the second semiconductor chip includes a logic chip, and
wherein the third semiconductor chip includes a memory chip.
